(19) United States
(12) Patent Application Publication
(10) Pub. No.: US 2008/0020510 A1
(43) Pub. Date: Jan. 24, 2008

(54) FABRICATION METHOD OF SEMICONDUCTOR DEVICE

(76) Inventors: Bunshi Kuratomi, Tokyo (JP); Fukumi Shimizu, Tokyo (JP); Yoichi Kawata, Tokyo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/779,312

(22) Filed: Jul. 18, 2007

(30) Foreign Application Priority Data
Jul. 21, 2006 (JP) 2006-199750

(51) Int. Cl. H01L 21/98

(52) U.S. Cl. 438/107; 257/E21.705

(57) ABSTRACT

A technique able to effect automation of a molding process corresponding to a multifarious small lot semiconductor device manufacturing process is provided. As to a frame supply unit, a lead frame conveying unit and molding press sets, which are each operated by a motor within a molding apparatus, the amount of operation of the motor is controlled in accordance with preset data so as to give an amount of operation matching the size of a lead frame. When the type of the lead frame changes, the data concerned is read and the amount of the operation of the motor is switched automatically.

### CROSS-REFERENCE TO RELATED APPLICATIONS

The disclosure of Japanese Patent Application No. 2006-199750 filed on Jul. 21, 2006 including the specification, drawings and abstract is incorporated herein by reference in its entirety.

### BACKGROUND OF THE INVENTION

The present invention relates to a semiconductor device fabricating technique and particularly to a technique applicable effectively to a molding process for resin-sealing electronic parts such as semiconductor chips mounted on a mounting substrate such as a lead frame.

In Japanese patent laid-open No. 2003-92305 (Patent Literature 1) is disclosed a technique for improving the productivity of a resin molding apparatus. According to this technique, a lead frame supply mechanism unit, a resin material supply mechanism unit and a molded product cutting mechanism are attached detachably to the molding apparatus.

In Japanese patent laid-open No. 2004-266153 (Patent Literature 2) is disclosed a resin molding apparatus wherein different types of semiconductor chips mounted on different types of substrates can be sealed with resin simultaneously with use of different shapes of sealing resin materials, thereby not only permitting simultaneous production of completely different types of products but also make it possible to attain a high manufacturing efficiency and cope with changes of demand quickly.

In Japanese patent laid-open No. Hei 7 (1995)-32415 (Patent Literature 3) is disclosed a resin molding apparatus wherein a molding unit in the apparatus constituted by a combination of minimum constituent units for sealing electronic parts with resin is combined with an additional another molding unit in a detachable state to mold different types of products simultaneously without increasing the mold size itself.

In Japanese patent laid-open No. Hei 9 (1997)-141685 (Patent Literature 4) is disclosed a resin molding apparatus having a resin tablet temperature control mechanism capable of strictly controlling the temperature of a resin tablet storage place.

In Japanese patent laid-open No. Hei 7 (1995)-263473 (Patent Literature 5) is disclosed a technique associated with a semiconductor molding apparatus having molding resin storage means. According to this technique, means for adjusting the temperature of the resin stored in the molding resin storage means is provided in a body of the semiconductor molding apparatus, thereby preventing the formation of voids and the occurrence of wire deformation in semiconductor molding.

In Japanese patent laid-open No. Hei 7 (1995)-32414 (Patent Literature 6) is disclosed a resin molding apparatus wherein a molding unit in the apparatus constituted by a combination of minimum constituent units for sealing electronic parts with resin is combined with an additional another molding unit, thereby permitting mass production in a simple manner without increasing the mold size itself.

In Japanese patent laid-open No. Hei 8 (1996)-197571 (Patent Literature 7) is disclosed a resin molding apparatus having plural molding units to seal electronic parts wherein when the operation of any of the molding units is stopped for maintenance work, the maintenance work for the stopped molding unit can be done while continuing the manufacture of molded products with use of the other molding units.

Patent Literatures:

1. Japanese patent laid-open No. 2003-92305

2. Japanese patent laid-open No. 2004-266153

3. Japanese patent laid-open No. Hei 7 (1995)-32415

4. Japanese patent laid-open No. Hei 9 (1997)-141685

5. Japanese patent laid-open No. Hei 7 (1995)-263473

6. Japanese patent laid-open No. Hei 7 (1995)-32414

7. Japanese patent laid-open No. Hei 8 (1996)-197571

### SUMMARY OF THE INVENTION

According to a molding process in the course of fabrication of a semiconductor device, a base such as a lead frame or a wiring substrate with electronic parts such as semiconductor chips (hereinafter referred to simply as “chips”) mounted thereon is received within a molding die and thereafter resin is injected into cavities of the molding die to form a resin sealing body which covers and protects the electronic parts.

The present inventors are studying a molding apparatus able to easily cope with multifarious small lot production of molded products (semiconductor devices). In multifarious small lot production of molded products, molding is performed in principle using an existing molding apparatus for mass production or a molding apparatus for a single frame because the following conditions are different: (a) the size (width and length) of a base with electronic parts mounted thereon, (b) mass of resin used, (c) specification of resin used, (d) the number of products obtained from one base, (e) flow path of resin based on the difference in the number of products obtained from one base, (f) molding conditions. Besides, since the production is basically a small lot production, the number of products in molding (the number of molding shots) varies from about 10 shots to about 100 shots.

According to the study made by the present inventors, the existing molding apparatus cannot satisfy all of the above conditions (a) to (f) in multifarious small lot production and therefore molding is performed not automatically but manually. Even when molding is performed automatically, it is necessary that a conveyance mechanism section in the molding apparatus be switched from one to another for each type of product to be molded. It takes time for this switching work and subsequent adjusting work. Therefore, if it is intended to shorten the switching work time for the conveyance mechanism section, save the adjusting work time after the switching work and reduce the investment in the switching unit for switching the conveyance mechanism section, investment is made in only the molding die for each product and the molding work is performed manually.

In multifarious small lot production, however, it is often required to develop products in a short period and manufacture the products less expensively. Therefore, the aforesaid manual molding work poses the problem that the manufacturing efficiency is deteriorated.

Besides, many of the existing molding apparatus employ a molding die of a structure such that molding is performed at a time for plural bases from the standpoint of improving the manufacturing efficiency. According to the structure of such a molding die, molding is performed at a time for at least two bases, thus giving rise to the problem that the fabrication of the molding die itself costs high.

Moreover, in the case where a worker in charge of maintenance of the molding apparatus also takes charge of any other process than the molding process, if it is intended to carry out the molding process automatically, there arises the problem that it becomes impossible to spare time for the switching work for the conveyance mechanism section to cope with multifarious small lot production and for the subsequent adjusting work.

There further arises the problem that a huge cost is required for fabricating the switching unit for switching the conveyance mechanism section in order to attain an automatic molding process coping with multifarious small lot production.

One object disclosed in the present invention is to provide a technique permitting the attainment of an automatic molding process coping with multifarious small lot production of semiconductor devices.

The following is a brief description of typical modes of the present invention as disclosed herein.

1. A method of fabricating a semiconductor device, using a molding apparatus for sealing plural types of bases with resin and comprising the steps of:

(a) mounting semiconductor chips over any of the bases, (b) conveying the base with the semiconductor chips mounted thereover to a molding press jig in the molding apparatus, (c) conveying tablets as sealing resin to the molding press jig, (d) pressing the tablets in the molding press jig to seal the semiconductor chips with the sealing resin, and (e) after the step (d), unloading the base from the molding press jig, wherein the molding apparatus includes a plurality of tablet storage means for storing plural types of the tablets type by type and a plurality of the molding press jigs having one molding die, the one molding die having a structure permitting insertion therein of one said base, with identification marks indicative of types to be fabricated being assigned to the bases, the tablet storage means and the molding press jigs respectively, in the step (b) the identification mark of the base is read and the base is conveyed to the molding press jig with the corresponding identification mark assigned thereto, and in the step (c) the tablets are taken out from the tablet storage means to which is assigned the identification mark corresponding to the identification mark read from the base in the step (b) and are then supplied to the molding press jig with the corresponding identification mark assigned thereto.

2. A method of fabricating a semiconductor device, using a molding apparatus for sealing plural types of bases with resin and comprising the steps of:

(a) mounting semiconductor chips over any of the bases, (b) conveying the base with the semiconductor chips mounted thereover to a molding press jig in the molding apparatus, (c) conveying tablets as sealing resin to the molding press jig, (d) pressing the tablets in the molding press jig to seal the semiconductor chips with the sealing resin, and (e) after the step (d), unloading the base from the molding press jig, wherein the molding apparatus includes a plurality of tablet storage means for storing plural types of the tablets type by type, a plurality of the molding press jigs having one molding die and a plurality of tablet conveying jigs for holding the tablets and supplying them to the molding press jig, the plural types of the tablets having one and same first plane size, the one molding die having a structure permitting insertion therein of one said base, with identification marks indicative of types to be fabricated being assigned to the bases, the tablet storage means and the molding press jigs respectively, in the step (b) the identification mark of the base is read and the base is conveyed to the molding press jig with the corresponding identification mark assigned thereto, and in the step (c) the tablets are taken out from the tablet storage means to which is assigned the identification mark corresponding to the identification mark read from the base in the step (b) and are then supplied to the molding press jig with the corresponding identification mark assigned thereto, and the tablet conveying jig holding the tablets is conveyed to the molding press jig with the corresponding identification mark assigned thereto.

3. A method of fabricating a semiconductor device, using a molding apparatus for sealing plural types of bases with resin and comprising the steps of:

(a) mounting semiconductor chips over any of the bases, (b) conveying the base with the semiconductor chips mounted thereover to a molding press jig in the molding apparatus, (c) conveying tablets as sealing resin to the molding press jig, (d) pressing the tablets in the molding press jig to seal the semiconductor chips with the sealing resin, and (e) after the step (d), unloading the base from the molding press jig, wherein the molding apparatus includes a plurality of tablet storage means for storing a plurality of the tablets of the same type and a plurality of the molding press jigs having one molding die, the one molding die having a structure permitting insertion therein of one said base, with identification marks indicative of types to be fabricated being assigned to the bases and the molding press jigs respectively, in the step (b) the identification mark of the base is read and the base is conveyed to the molding press jig with the corresponding identification mark assigned thereto, and in the step (c) the tablets in the number of tablets corresponding to the identification mark read from the base in the step (b) are taken out from the tablet storage means and are then supplied to the molding press jig with the corresponding identification mark assigned thereto.

The following is a brief description of effects obtained by the typical modes of the present invention as disclosed herein.

(1) The amount of operation of a motor for operating components installed within the molding apparatus is controlled in accordance with preset data so that the amounts of operation of the components match the size of a lead frame (base), and when the type of the lead frame changes, the data is read and the amount of operation of the motor is switched automatically. By so doing, even when the type of the lead frame changes, the components installed within the molding apparatus can be used as they are. That is, it is possible to implement the automation of a molding process corresponding to the semiconductor device manufacturing process in multifarious small lot production.
(2) Even when the type of the lead frame changes, the components installed within the molding apparatus can be used as they are and the amount of operation of the motor for operating those components is changed automatically, so it is possible to omit the work for changing the components in accordance with the type of the lead frame. Besides, since the amount of operation of the motor switches automatically, it is also possible to omit fine adjustment of those components when the type of the lead frame changes. As a result, it is possible to shorten TAT (Turn Around Time) in multifarious small lot production of semiconductor devices.
(3) Since the molding process is carried out automatically and not by the worker in charge of maintenance, it is possible to stabilize the conveyance of the lead frame in the molding apparatus and hence possible to improve the semiconductor device manufacturing yield.

### BRIEF DESCRIPTION OF THE DRAWINGS

FIG. 1 is a plan view showing an example of outline of a lead frame used in a semiconductor device manufacturing process according to an embodiment of the present invention;

FIG. 2 is a flow chart explaining a principal portion of the semiconductor device manufacturing process;

FIG. 3 is a plan view of a principal portion of the lead frame for explaining in detail a molding process in the manufacture of the semiconductor device;

FIG. 4 is a plan view of a principal portion of the lead frame for explaining in detail the molding process in the manufacture of the semiconductor device;

FIG. 5 is a plan view of a principal portion of the lead frame for explaining in detail the molding process in the manufacture of the semiconductor device;

FIG. 6 is a plan view of an upper mold of a molding die used in the molding process during manufacture of the semiconductor device;

FIG. 7 is a plan view of a lower mold of the molding die shown in FIG. 6;

FIG. 8 is a plan view of an upper mold of a molding die used in the molding process during manufacture of the semiconductor device;

FIG. 9 is a plan view of a lower mold of the molding die shown in FIG. 8;

FIG. 10 is a sectional view of the upper mold taken along line A-A in FIG. 8;

FIG. 11 is a sectional view of the lower mold taken along line B-B in FIG. 9;

FIG. 12 is a perspective view of a principal portion, showing an example of a cull/sub-runner break processing method in the molding process during manufacture of the semiconductor device;

FIG. 13 is a sectional view of a principal portion, explaining a cutting process after the molding process in the manufacture of the semiconductor device;

FIG. 14 is a sectional view of a principal portion in the cutting process which follows FIG. 13;

FIG. 15 is a sectional view of a principal portion in the cutting process which follows FIG. 14;

FIG. 16 is an appearance diagram of a molding apparatus used in the semiconductor device manufacturing process;

FIG. 17 is a plan view of the interior of the molding apparatus;

FIG. 18 is a plan view of a tablet conveying jig disposed within the molding apparatus;

FIG. 19 is a side view thereof;

FIG. 20 is an explanatory diagram showing a relation between ID pins attached to the tablet conveying jig shown in FIGS. 18 and 19 and ID of the same jig;

FIG. 21 is an explanatory diagram showing a relation between a tablet control temperature used in the molding process during manufacture of the semiconductor device and the time taken to 10% deterioration of the tablet quality;

FIG. 22 is a sectional view of a principal portion, explaining a molding press setting operation in the molding process during manufacture of the semiconductor device;

FIG. 23 is a sectional view of a principal portion, explaining a molding press setting operation which follows FIG. 22;

FIG. 24 is a sectional view of a principal portion, explaining a molding press setting operation which follows FIG. 23;

FIG. 25 is a sectional view of a principal portion, explaining a molding press setting operation which follows FIG. 24;

FIG. 26 is a sectional view of a principal portion, explaining a molding press setting operation in a molding process during manufacture of a semiconductor device according to another embodiment of the present invention;

FIG. 27 is a sectional view of a principal portion, explaining a molding press setting operation which follows FIG. 26;

FIG. 28 is a sectional view of a principal portion, explaining a molding press setting operation which follows FIG. 27;

FIG. 29 is a sectional view of a principal portion, explaining a molding press setting operation which follows FIG. 28;

FIG. 30 is a plan view of a principal portion of a lower mold of a molding die used in a molding process during manufacture of a semiconductor device according to a further embodiment of the present invention; and

FIG. 31 is a plan view of a principal portion of a lower mold of a molding die used in the molding process during manufacture of the semiconductor device according to the further embodiment.

### DETAILED DESCRIPTION OF PREFERRED EMBODIMENTS

Before describing the present invention in detail, the meanings of terms as used herein will be described below.

By “wafer” is meant any of a single crystal silicon substrate (generally circular in plan) used in fabricating a semiconductor element or an integrated circuit, SOI (Silicon On Insulator) substrate, epitaxial substrate, sapphire substrate, glass substrate, other insulating and semi-insulating or semiconductor substrates, as well as composite substrates thereof. By the term “semiconductor device” as referred to herein is meant to include not only those formed on such semiconductor or insulator substrates as silicon wafer and sapphire substrates but also those formed on other insulating substrates such as glass substrate, e.g., TFT (Thin Film Transistor) and STN (Super-Twisted-Nematic) liquid crystal, unless otherwise mentioned.

By “device surface or element-forming surface” is meant a main surface of wafer on which device patterns corresponding to plural chip regions are formed by lithography.

By “multi-layer wiring substrate” is meant a mounting substrate having a structure capable of mounting chips thereon and fabricated by bonding metallic foil such as copper foil to the surface of a base formed of a resin material, laminating plural layers of such foiled bases and coupling the wiring materials between the layers electrically via through holes.

By “molding apparatus” is meant an apparatus which performs molding with use of a thermosetting resin and which comprises a molding press and a molding die both to be described later.

By “molding press” is meant a press for molding a thermoplastic resin, including a die clamping mechanism and a transfer mechanism for the injection of resin.

By “molding die” is meant a resin molding die to be attached to the molding apparatus, comprising pots, plungers, runners, gates, cavities and ejectors, which will be described later.

By “pot” is meant a molding material (resin) supply port in the molding die. A pot and a plunger make a pair, the pot functioning as a cylinder and the plunger functioning as a piston.

By “plunger” is meant a part for injecting the molding material present within a pot into a cavity in the molding apparatus and pressurizing and holding the material.

By “runner” is meant a portion from cull to gate and a material portion solidified therein in a molten material pouring route for a cavity in the molding die.

By “cull” is meant a recess formed in the molding die for branching the resin injected with the plunger into the runner in a state of constant pressure, as well as a resin portion remaining and solidified in the recess.

By “gate” is meant a pouring port through which molten resin is poured into a cavity in the molding die.

By “cavity” is meant a resin pouring portion between upper and lower molds in the molding die, corresponding to a molded product.

By “ejector” is meant an ejecting mechanism or device provided in the molding die for taking out a molded product from the die.

Where required for convenience' sake, the following embodiments will each be described in a divided manner into plural sections or embodiments, but unless otherwise mentioned, they are not unrelated to each other but are in a relation such that one is a modification or a detailed or supplementary explanation of part or the whole of the other.

In the following embodiments, when reference is made to the number of elements (including the number, numerical value, quantity and range), no limitation is made to the number referred to, but numerals above and below the number referred to will do as well unless otherwise mentioned and except the case where it is basically evident that limitation is made to the number referred to.

Further, it goes without saying that in the following embodiments their constituent elements (including constituent steps) are not always essential unless otherwise mentioned and except the case where they are considered essential basically obviously. It goes without saying that in the following embodiments, “comprising A” when described in connection with a constituent element or the like does not exclude other elements except the case where it is described clearly that limitation is made to only the element referred to.

Likewise, it is to be understood that when reference is made to the shapes and a positional relation of constituent elements in the following embodiments, those substantially closely similar to or resembling such shapes, etc. are also included unless otherwise mentioned except the case where a negative answer is evident basically. This is also true of the foregoing numerical value and range.

When reference is made to the material or the like, the material specified is a principal material and does not exclude secondary elements, additives and additional elements unless otherwise mentioned and except the case where a negative answer is evident basically or in view of the situation. For example, unless otherwise mentioned, silicon material includes not only pure silicon but also added impurities and binary and ternary alloys (e.g., SiGe) containing silicon as a principal element.

In all of the drawings for explaining the embodiments, in principle, portions having the same functions are identified by the same reference numerals, and repeated explanations thereof will be omitted.

In the drawings used in the embodiments, even a plan view may be partially hatched to make it easier to see.

As to the details of the molding process adopted in the present invention, it is disclosed in Japanese Patent Application No. 2004-173745 involving the present inventors and associated inventors.

Embodiments of the present invention will be described in detail hereinunder with reference to the drawings.

### First Embodiment

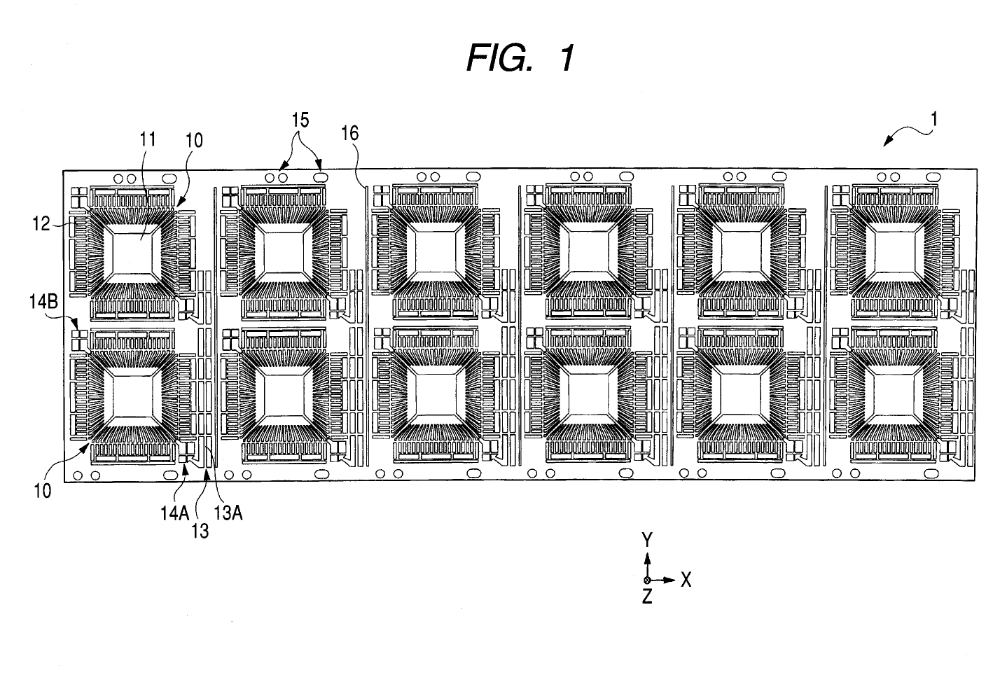

FIG. 1 is a plan view showing an example of outline of a lead frame (base) 1 used in this first embodiment. The lead frame 1 shown in FIG. 1 is, for example, a matrix type lead frame for QFP (Quad Flat Package). According to the structure of this lead frame, if it is assumed that the longitudinal direction (X-axis direction) of the lead frame 1 is column and the direction (Y-axis direction) orthogonal to the column direction is row, unit frames 10 each corresponding to one product are arranged in 6 rows by 2 columns. The matrix type lead frame used in this first embodiment has two or more unit frames in each of row and column. Further, in this first embodiment, the thickness direction of the lead frame orthogonal to the above X and Y axes is assumed to be Z-axis direction.

Each unit frame 10 includes a tab 11, a large number of leads 12 arranged so as to surround the tab 11, a gate portion 14A formed at a corner of a package area (cavity portion) as a resin sealing area including a semiconductor chip (hereinafter referred to simply as “chip”), and a gate portion 14B formed at a diagonal corner opposite to the gate portion 14A in the package area. The tab 11 is a portion on which a chip is to be mounted by die bonding. The leads 12 are portions coupled electrically to pads formed by wire bonding on a main surface of the chip. The gate portion 14A is a portion serving as an inlet when resin is injected into the package area. Plural holes 15 and slits 16 are formed between adjacent unit frames 10 and around each unit frame 10. These holes and slits are for positioning the lead frame or for mitigating a strain of the lead frame induced by the injection of resin.

A runner portion 13 serving as a resin influent path is provided between unit frames 10 which are adjacent to each other in the column direction. The runner portion has a lattice-like pattern comprising plural support leads 13A.

Further, though not shown, an identification mark indicative of type is assigned to the lead frame 1.

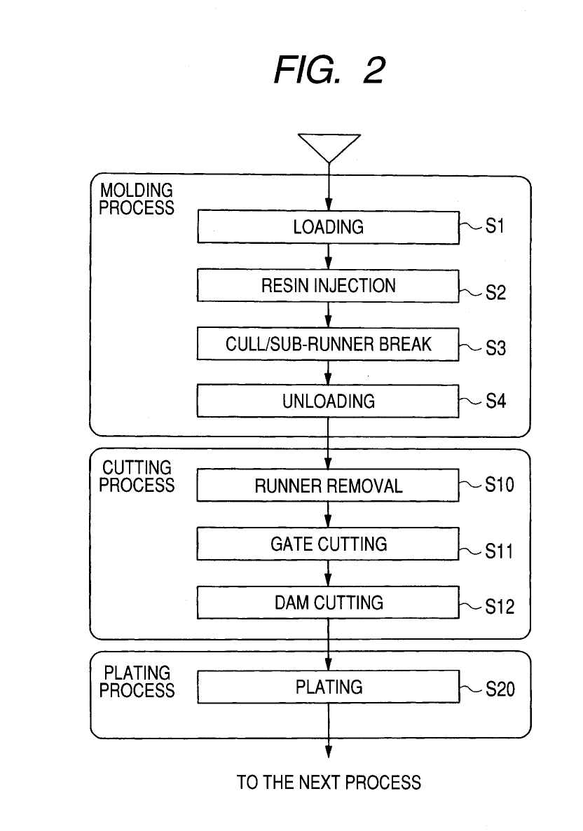

FIG. 2 is a flow chart showing principal portions of a semiconductor device manufacturing process according to this first embodiment. Using such a lead frame 1 as shown in FIG. 1, a molding process using a molding apparatus, a cutting process using a cutter, and a plating process using a plating apparatus, are performed in this order.

In the molding process are included a loading step (S1) of loading the lead frame 1 with chips wire-bonded thereto into a molding apparatus and setting it to a predetermined position, a resin injection step (S2) of injecting resin to the thus-set lead frame 1 with use of both upper and lower molds, a cull/sub-runner break step (S3) of removing remaining resin of cull and sub-runner portions resulting from the injection of resin, and an unloading step (S4) of taking out the lead frame 1 after the cull/sub-runner break step from the predetermined position and carrying it out to the next apparatus.

In the cutting process are included a runner removing step (S10) of removing remaining resin of runner portions resulting from the resin injection step (S2), a gate cutting step (S11) of removing remaining resin of gate portions, and a dam cutting step (S12) of removing lead-to-lead dam bars in the lead frame 1 and resin remaining around the dam bars. In the plating process is included a plating step (S20) of plating outer leads of package resin with use of solder for example.

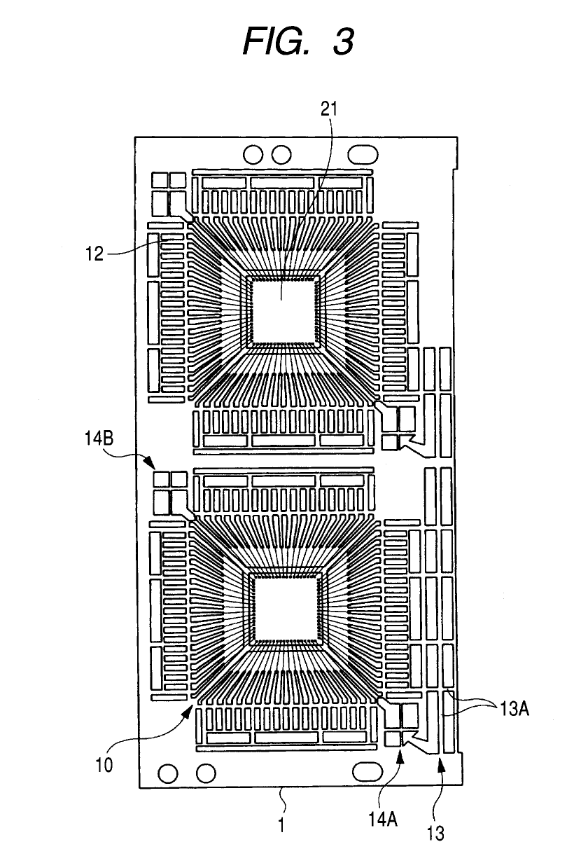

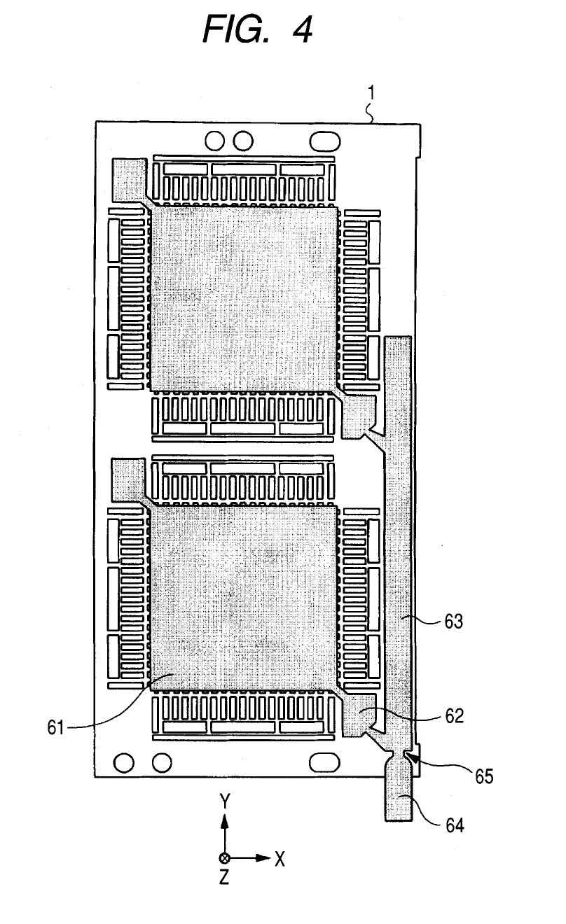

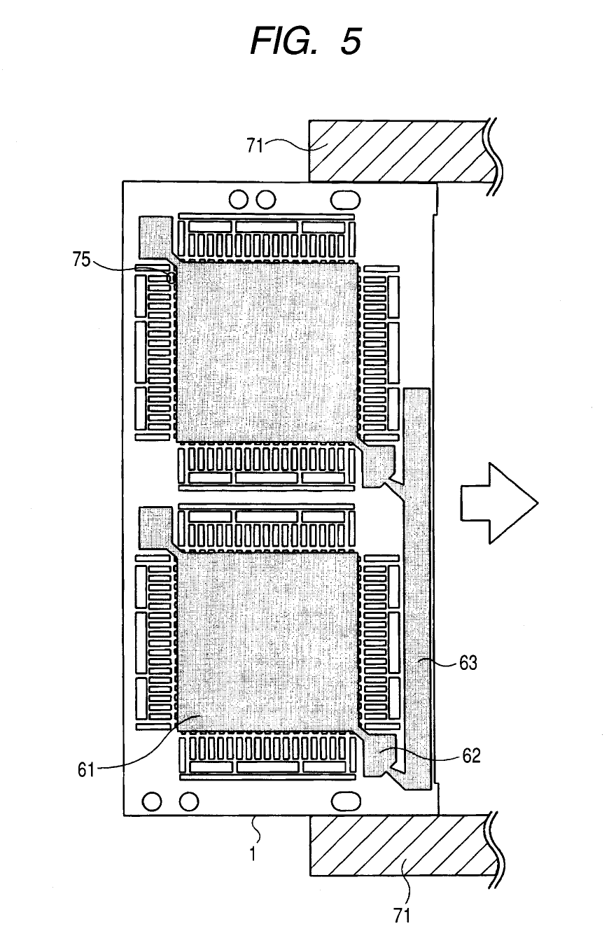

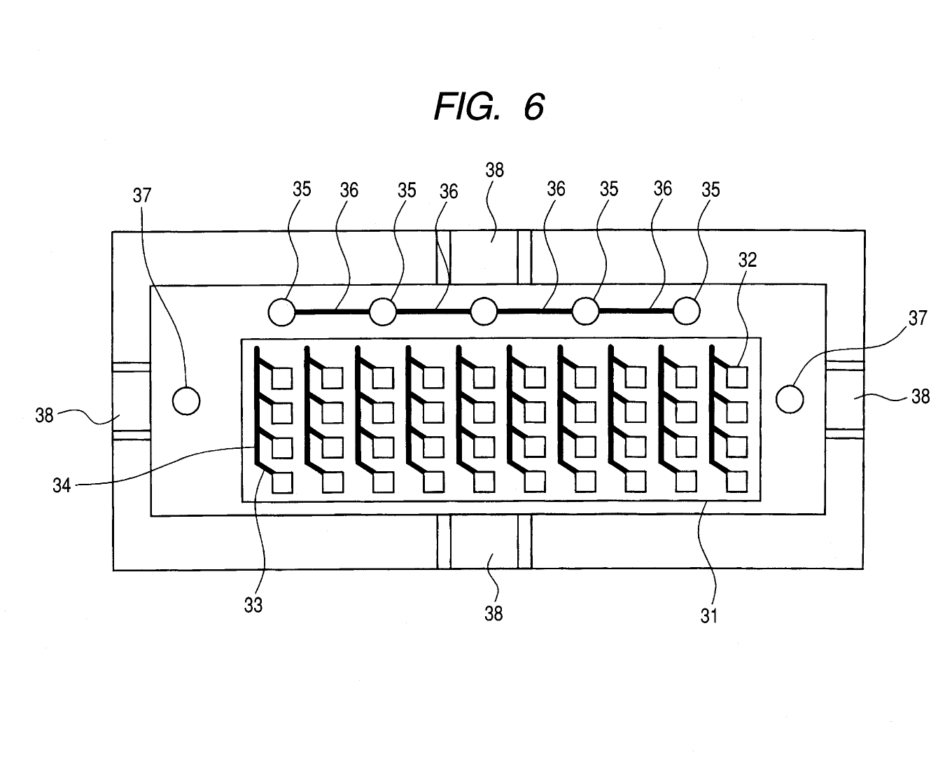

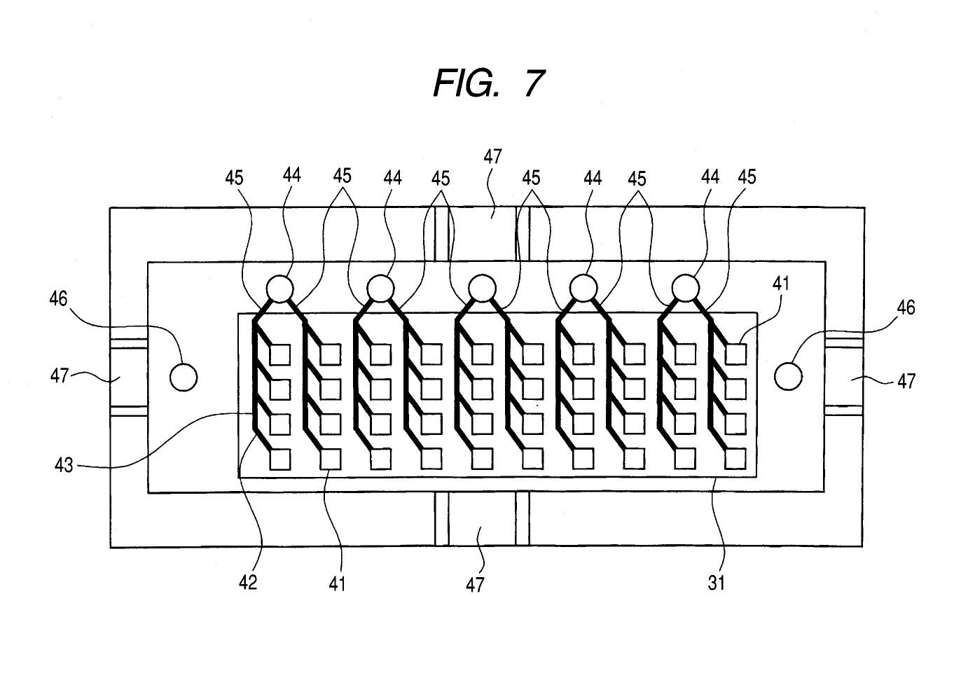

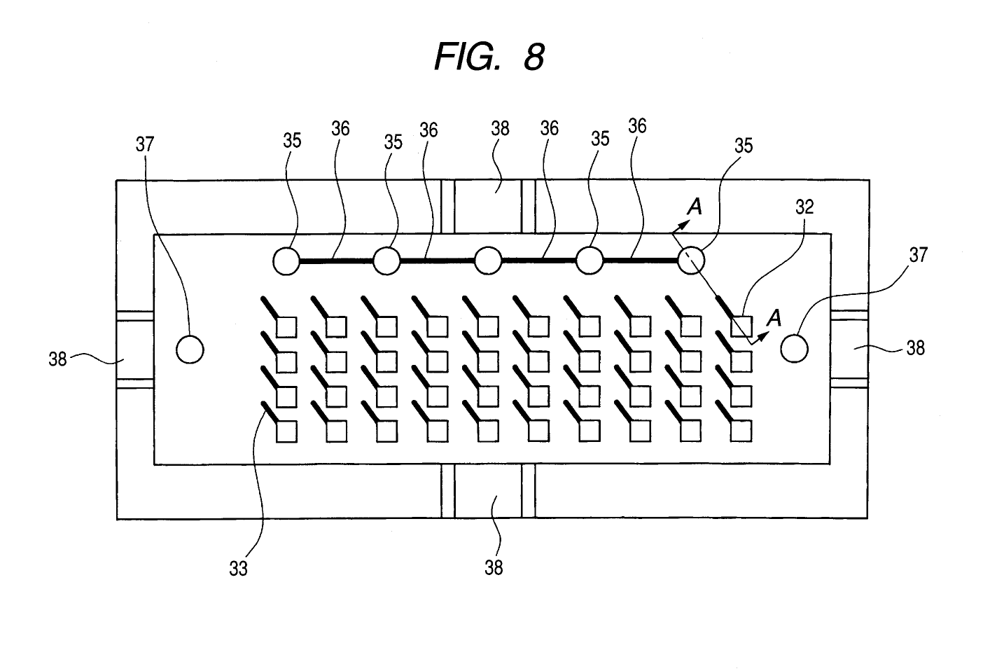

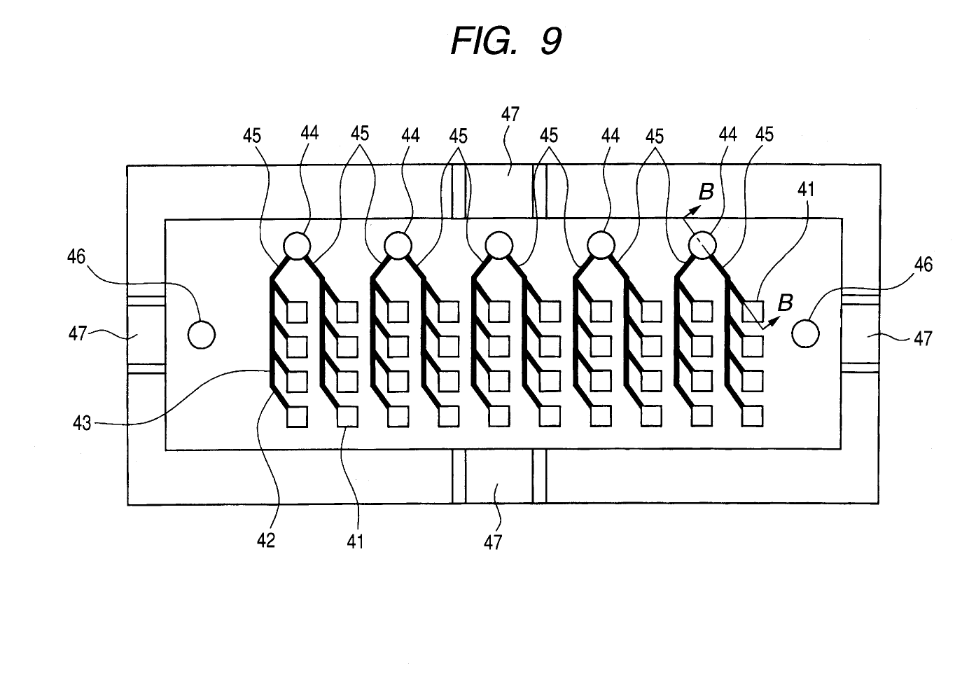

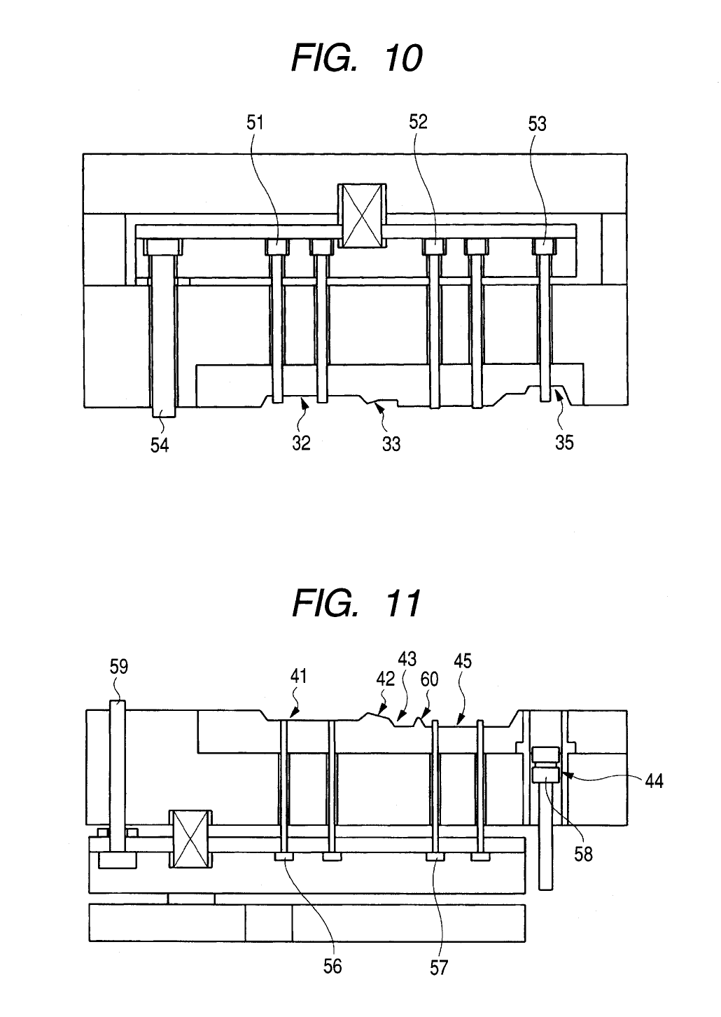

The molding process will be described in detail with reference to FIGS. 3 to 12. FIGS. 3 to 5 are plan views of a principal portion of the lead frame 1 for describing in detail the molding process shown in FIG. 2, of which FIG. 3 shows the lead frame 1 before the injection of resin, FIG. 4 shows the lead frame 1 after the injection of resin, and FIG. 5 shows the lead frame 1 being unloaded after cull/sub-runner break. FIGS. 6 and 7 are plan views showing the structure of a molding die used in the molding process shown in FIG. 2, of which FIG. 6 is a plan view of an upper mold and FIG. 7 is a plan view of a lower mold. FIGS. 8 and 9 are plan views showing the structure of a molding die different from the molding die shown in FIGS. 6 and 7, of which FIG. 8 is a plan view of an upper mold and FIG. 9 is a plan view of a lower mold. FIGS. 10 and 11 are sectional views of principal portions, each showing a sectional structure of the molding die shown in FIGS. 8 and 9, of which FIG. 10 is a sectional view of the upper mold taken along line A-A in FIG. 8 and FIG. 11 is a sectional view of the lower mold taken along line B-B in FIG. 9. FIG. 12 is a perspective view of a principal portion, showing an example of a cull/sub-runner break processing method in the molding process (see FIG. 2).

In FIG. 3 there is shown a state in which a chip 21 is die-bonded onto each tab of the lead frame 1 and is wire-bonded to the leads 12 of the lead frame. FIG. 3 shows such a state for one row of the lead frame 1 shown in FIG. 1. Using such upper and lower molds as shown in FIGS. 6 to 11, resin is injected to the lead frame 1.

The upper mold shown in FIG. 6 permits only one lead frame 1 to be loaded therein. In case of forming a molding die so as to permit plural lead frames 1 to be loaded therein, the production efficiency can be improved, but the molding die becomes large-sized and the structure thereof becomes more complicated, resulting in an increase of the die fabrication cost. Therefore, when a multifarious small lot production of packages (semiconductor devices) is intended, the type of the molding die itself also increases and thus the molding die which permits loading of plural lead frames 1 is unsuitable. On the other hand, the molding die used in this embodiment permits loading of only one lead frame 1, so in comparison with the structure permitting loading of plural lead frames 1, the structure according to this embodiment can be reduced in size and simplified and it is possible to reduce the fabrication cost of the molding die itself. That is, the fabrication cost of the package of this first embodiment can be reduced.

In the upper mold used in this first embodiment, as shown in FIG. 6, cavity portions 32 as concave molds, gate portions 33 and runner portions 34 are provided in a loading area 31 of the lead frame 1. Outside the lead frame loading area 31 are provided cull portions 35 corresponding to resin supply sources and coupling runners 36 for coupling between the cull portions 35. There also are provided return pin driving holes 37 necessary to ejecting the upper mold after the injection of resin and convex wedges 38 for alignment between the upper and lower molds.

The lower mold shown in FIG. 7 has a configuration corresponding to the upper mold shown in FIG. 6. Like the upper mold, the lower mold has cavity portions 41 as concave molds, gate portions 42 and runner portions 43 in the loading area 31 of the lead frame 1. The lower mold is further provided with pot portions 44 corresponding to the cull portions 35 of the upper mold and sub-runner portions 45 as channels coupling the pot portions 44 and the runner portions 43 with each other. There also are provided return pin driving holes 46 necessary to ejecting the lower mold after the injection of resin and concave wedges 47 for alignment between the upper and lower molds.

The injection of resin is performed by sandwiching the lead frame 1 in between the upper and lower molds and supplying resin to the pot portions 44. The resin supplied to the pot portions 44 passes through the sub-runner portions 45, the passes through the runner portions 34, 43 and the gate portions 33, 42 positioned on both surfaces of the lead frame 1 and is injected into the cavity portions 32 and 41.

The upper mold shown in FIG. 8 corresponds to the structure of the upper mold shown in FIG. 6 except that the runner portions 34 are omitted. Like the structure shown in FIG. 6, the upper mold shown in FIG. 8 has cavity portions 32, gate portions 33, cull portions 35 and coupling runners 36. It is further provided with return pin driving holes 37 and convex wedges 38. The lower mold shown in FIG. 9, like the lower mold shown in FIG. 7, has cavity portions 41, gate portions 42, runner portions 43, pot portions 44 and sub-runner portions 45. It is further provided with return pin driving holes 46 and concave wedges 47.

An A-to-A sectional structure as a resin influent path from the cull portions 35 to cavity portions 32 shown in FIG. 8 and a B-to-B sectional structure as a resin influent path from the pot portions 44 to the cavity portions 41 shown in FIG. 9 are as shown in FIGS. 9 and 11, respectively.

As shown in FIG. 10, the upper mold shown in FIG. 8 further has ejector pins 51 provided so as to be projectable to the cavity portions 32, ejector pins 52 provided so as to be projectable to the runner portions 43 (see FIG. 11) and the sub-runner portions 45 (see FIG. 11), ejector pins 53 provided so as to be projectable to the cull portions 35, and return pins 54 corresponding to the holes 37 shown in FIG. 8.

As shown in FIG. 11, the lower mold shown in FIG. 9 further has ejector pins 56 provided so as to be projectable to the cavity portions 41, ejector pins 57 provided so as to be projectable to the runner portions 43 and the sub-runner portions 45, plungers 58 serving as pistons for sending out resin set in the pot portions 44, and return pins 59 corresponding to the holes 46 shown in FIG. 9. In the lower mold there also are provided convex portions 60 for thinning the resin at the joints between the runner portions 43 and the sub-runner portions 45.

For the injection of resin, the lead frame 1 is sandwiched in between the upper and lower molds and resin is supplied to the pot portions 44. The resin thus supplied to the pot portions 44 is sent out by the plungers 58, passes through the sub-runner portions 45 and the runner portions 43, then passes through the gate portions 33 and 34 positioned on both surfaces of the lead frame 1 and is injected into the cavity portions 32 and 41. After hardening of the injected resin, the upper and lower molds and the lead frame are separated from one another by the ejector pins 51-53, 56, 57 and the return pins 54, 59, whereby the lead frame 1 assumes such a state as shown in FIG. 4.

As shown in FIG. 4, the thus resin-sealed lead frame 1 has resin 61 present in the cavity portions including the chips 21 and inner leads serving as partial regions of the leads 12, resin 62 remaining in the gate portions, and resin 64 remaining in the sub-runner portions. The resin 64 remaining in the sub-runner portions is coupled to the resin remaining in the cull portions (not shown). Constrictions 65 are present respectively in the joints between the resin 63 remaining in the runner portions and the resin 64 remaining in the sub-runner portions and the resin thickness (in Z-axis direction) is small in those constrictions. In addition, the resin width (in X-axis direction) is also made small by the shape of the molding die.

In case of using the molding die shown in FIGS. 6 and 7, the resin 63 remaining in the runner portions assumes an adhered state to both surfaces of the lead frame 1, while in case of using the molding die shown in FIGS. 8 and 9, the resin 63 assumes an adhered state to one surface of the lead frame 1. It is optional whether the resin 63 remaining in the runner portions is to be adhered to both surfaces or to one surface, but the following effects are obtained in case of both-surface adhesion.

First, the support leads 13A in the runner portions 13 shown in FIG. 3 can be sandwiched by resin, and after hardening of the resin, the support leads 13A and the resin can be rendered integral with each other. Next, the runner portions 13 can be made thick in Z-axis direction by using both surfaces of the lead frame 1, whereby the resistance at the time of resin injection can be made small. Moreover, since a thermal stress is applied uniformly from both surfaces at the time of resin injection, it is possible to diminish warp or the like of the lead frame 1. Further, by making the resin 63 remaining in the runner portions thicker than the package resin at both surfaces it is possible to prevent damage to the package surface when plural lead frames with the resin 63 remaining in the runner portions are stacked.

The molding die in this first embodiment described above in connection with FIGS. 6 to 11 may be provided with a film unit mechanism to cope with laminate molding.

A description will now be given about the cull/sub-runner break step (S3) in the molding process which has been referred to above in connection with FIG. 2. In this step, for the lead frame 1 which is in such a state as shown in FIG. 4, the resin 64 remaining in the sub-runner portions and the resin remaining in the cull portions (not shown) are removed by for example such a method as shown in FIG. 12.

More specifically, the lead frame 1 shown in FIG. 4 and a break plate 70 are shown in FIG. 12. The break plate 70 is provided for example in the molding apparatus and can be moved vertically and transversely (in X-, Y- and Z-axis directions) by control of the apparatus. The break plate 70 is brought into contact with the resin 64 remaining in the sub-runner portion at a position as close as possible to the boundary between it and the lead frame 1 and is forced downward (in Z-axis direction) to remove the resin 64 remaining in the sub-runner portions and the resin remaining in the cull portions coupled thereto. At this time, since the constrictions 65 are formed respectively in the joints between the resin 63 remaining in the runner portions and the resin 64 remaining in the sub-runner portions, the remaining resin 63 and the remaining resin 64 are separated from each other at the position of each constriction 65. This gate break step does not require a highly accurate position adjustment and therefore can ensure a high throughput. Moreover, a common break plate 70 can be used even if the type of the lead frame used changes. Also as to the position where the brake plate 70 is used, it can be made a common position. Consequently, it is possible to reduce the cost required for the break plate 70.

In FIG. 12 there is shown only a unit frame of one row, but actually plural rows of unit frames are present in the column direction (X-axis direction). In this case, by using a break plate 70 proportional to the length in the column direction, resin remaining in sub-runner portions and resin remaining in cull portions can be removed by a single operation in a matrix type lead frame having plural rows and columns.

By the cull/sub-runner break step described above the lead frame assumes such a state as shown in FIG. 5. In the lead frame shown in FIG. 5, the resin remaining in the sub-runner portions has already been removed, but the resin 63 remaining in the runner portions is left unremoved. The molding process is ended in this state, followed by unloading. In the unloading step, the lead frame 1 is put on a conveyor rail 71 having guides on both sides thereof and is conveyed toward a cutter for the cutting process.

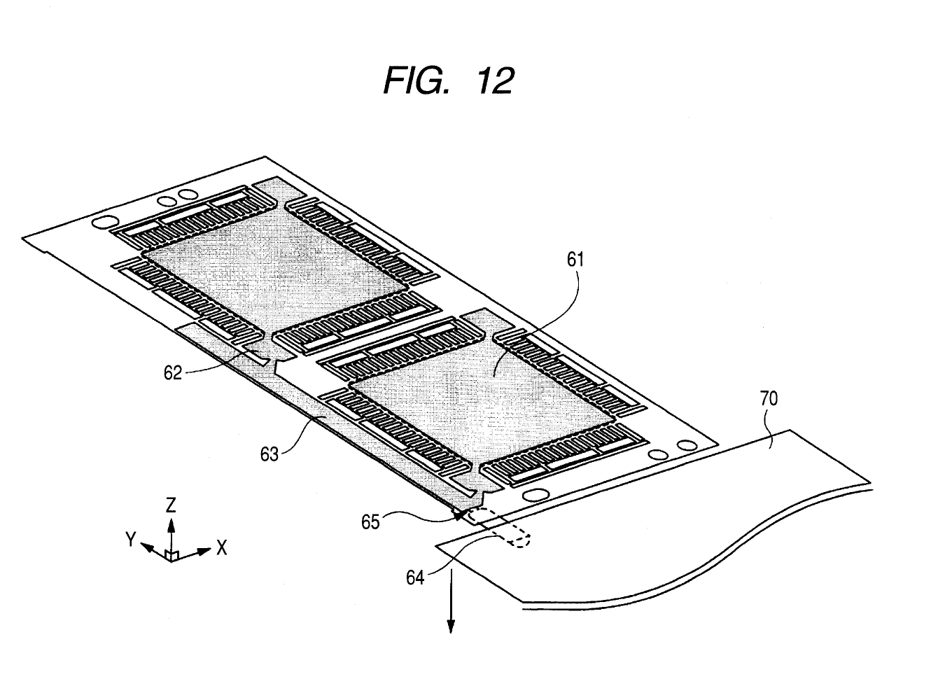

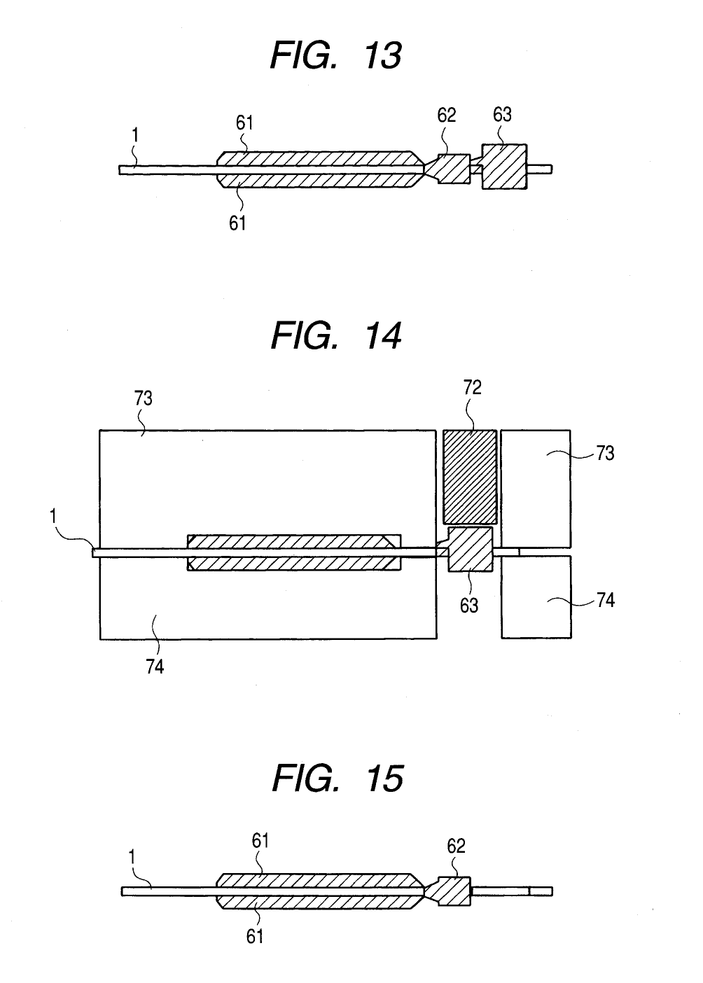

Next, the cutting process shown in FIG. 2 will be described with reference to FIGS. 13 to 15. FIGS. 13 to 15 are sectional views of a principal portion for explaining the cutting process in detail, of which FIG. 13 shows the lead frame 1 before the cutting process, FIG. 14 shows the lead frame 1 being subjected to a runner removing operation, and FIG. 15 shows the lead frame 1 after the runner removing operation.

In FIG. 13 there is shown an example of a section of the lead frame 1 shown in FIG. 5 in a plane comprising X and Z axes. Resin 61 which overlies the lead frame 1, resin 61 which underlies the lead frame 1, resin 62 remaining in a gate portion and resin 63 remaining in a runner portion are shown in FIG. 13. The resin 63 remaining in the runner portion is in the shape formed when using such a both-surface channel type molding die as shown in FIGS. 6 and 7.

In the lead frame 1, the resin 63 remaining in the runner portion is removed using for example such an ejector punch 72 as shown in FIG. 14. More specifically, the lead frame 1 is fixed by sandwiching it in between the a cutting mold 73 for the upper surface and a cutting mold 74 for the lower surface and pushing down the resin 63 with use of the ejector punch 72 or the like.

As described above in connection with FIGS. 1 and 3, the resin 63 remaining in the runner portions is in a state such that the runner portions 13 of the lead frame 1 having a lattice-like pattern comprising the support leads 13A are sandwiched with resin in between upper and lower surfaces. In case of using such a one-surface channel type molding die as shown in FIGS. 8 and 9, resin is adhered to the upper surface of the lattice-like pattern.

By pushing the ejector punch 72 against the resin 63 remaining in the runner portions, the support leads 13A covered with resin are broken off from the lead frame 1, whereby the resin 63 remaining in the runner portions including the support leads 13A can be removed. Therefore, in order to facilitate the breakage, it is preferable that the support leads 13A shown in FIGS. 1 and 3 be formed so as to have a small thickness (in Z-axis direction). However, if the thickness is made small to excess, the strength weakens, with a consequent possibility of damage due to for example a thermal strain at the time of resin injection. In view of this point it is preferable that the thickness in question be, say, 50 μm or so.

In order to facilitate breakage of the runner portions and prevent the resin in the runner portions from peeling off and becoming a generation source of dust particles during conveyance for shift from the molding process to the cutting process, it is preferable that the lattice-like pattern and the resin be rendered integral with each other to a satisfactory extent using such a both-surface channel type molding die as shown in FIGS. 6 and 7. Although the lattice-like pattern is used in FIGS. 1 and 3, the shape of the runner portions in the lead frame is not limited thereto, but there may be adopted any other shape insofar as the shape adopted maintains a moderate strength and permits easy breakage of the runner portions under the action of an external force such as the operation of the ejector punch 72.

By going through the above process the resin remaining in the runner portions is removed and the lead frame comes into a state having resin 61 and resin 62 remaining in the gate portions, as shown in FIG. 15. Therefore, as in the conventional cutting process, the resin 62 remaining in the gate portions is removed, followed by removal of such leads 12 and dam bars 75 coupling the leads 12 as shown in FIG. 5. Although the removal of the resin 62 remaining in the gate portions and that of the resin 63 remaining in the runner portions are here performed in a separate manner, both may be performed at a time because their contents are almost the same.

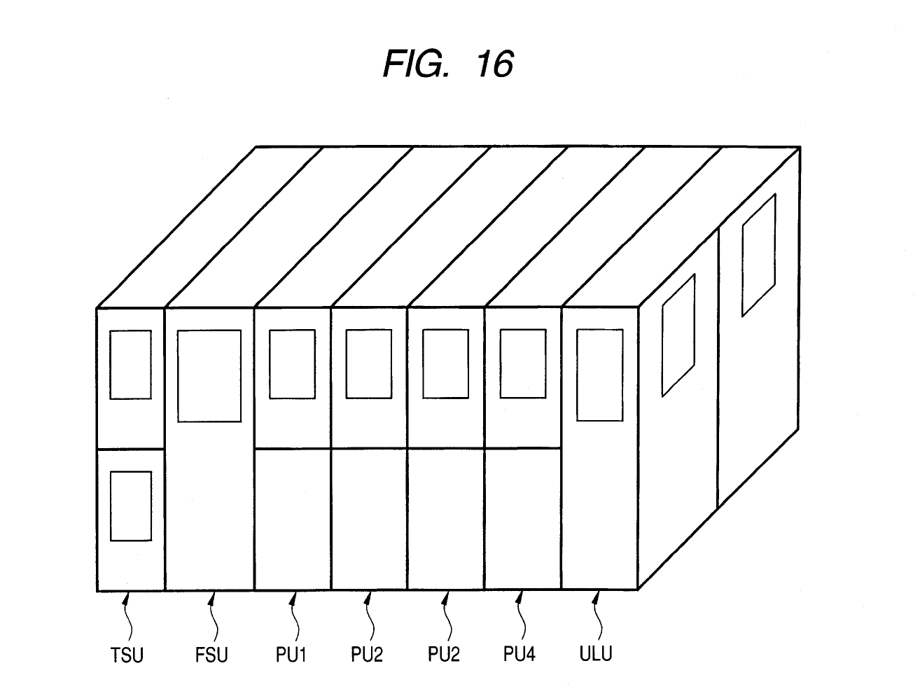

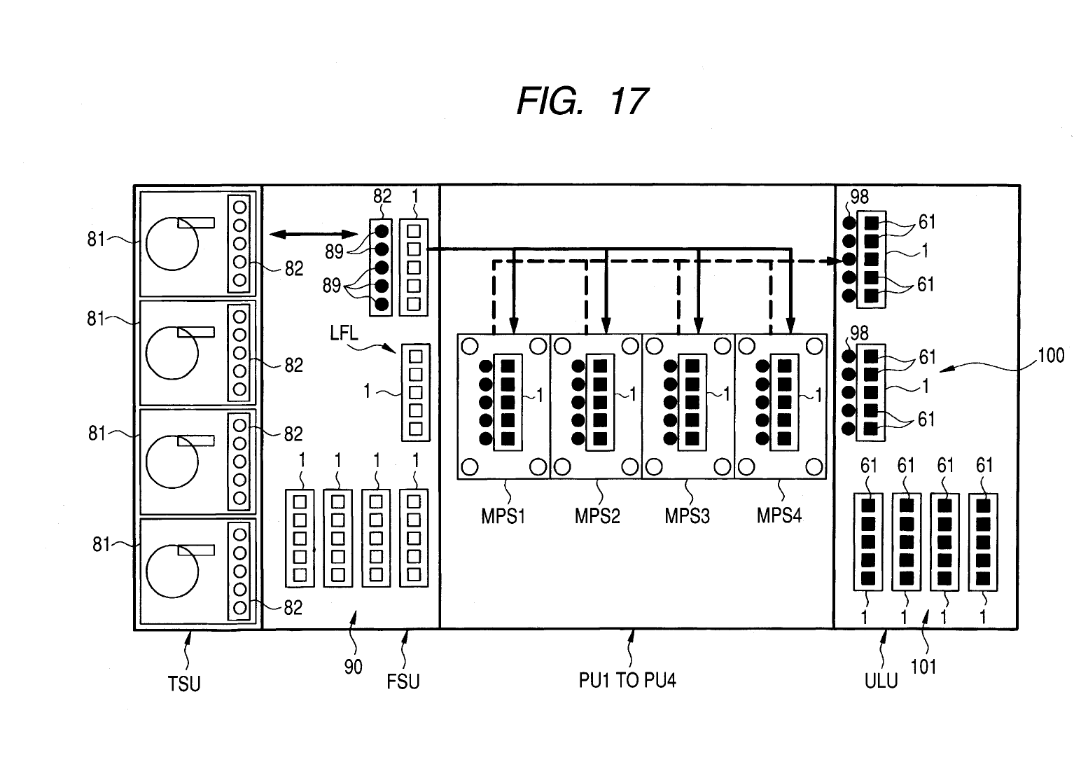

A detailed description will now be given about the molding apparatus according to this first embodiment which is used in the molding process shown in FIG. 2. FIG. 16 is an appearance diagram of the molding apparatus and FIG. 17 is a plan view showing an internal structure of the molding apparatus.

The molding apparatus according to this first embodiment comprises a tablet supply unit TSU, a frame supply unit FSU, press units PU1 to PU4, and an unloader unit ULU.

The tablet supply unit TSU is provided with plural tablet stockers (tablet storage means) 81 for the storage of tablets serving as molding (sealing) resin. In FIGS. 16 and 17 there is shown an example in which four tablet stockers 81 in plan are arranged in two stages. Tablets are stored type by type in the tablet stockers 81. Only one type of tablets are stored in one tablet stocker. Identification marks are assigned to the tablet stockers each individually and the type of stored tablets can be recognized from the identification mark concerned. Tablets taken out from any of the tablet stockers 81 are held by a tablet conveying jig 82 and are conveyed to the frame supply unit FSU.

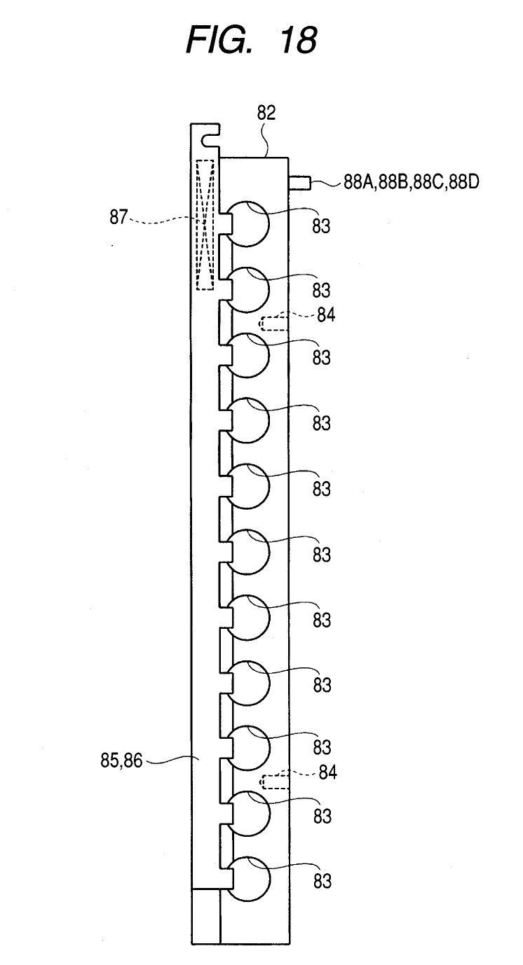

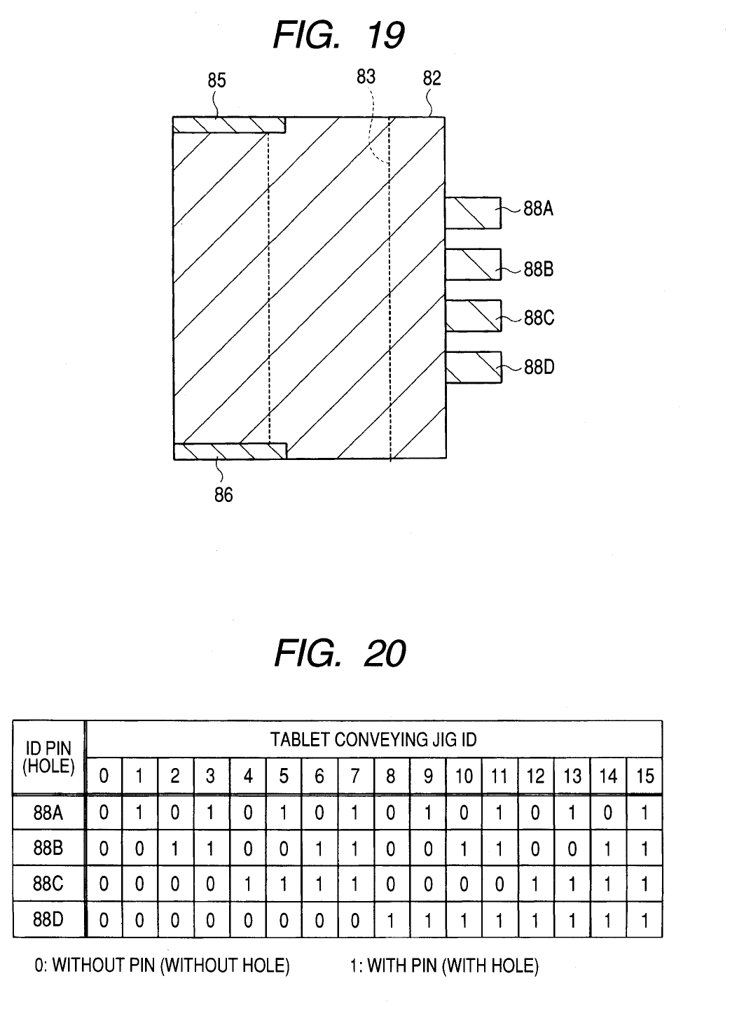

FIGS. 18 and 19 are a plan view and a sectional view, respectively, of the tablet conveying jig 82.

In the tablet conveying jig 82, as shown in FIGS. 18 and 19, there are provided plural holes 83 for receiving tablets therein and plural holes 84 to be used for positioning of the tablet conveying jig 82 in the molding apparatus. Tablet stoppers 85 and 86 are disposed above and below the tablet conveying jig 82 and are urged to the tablet conveying jig 82 with the resilience of springs 87. The holes 83 are closed partially or wholly by the tablet stoppers 85 and 86 to prevent the tablets from falling off from the holes 83 during conveyance.

The tablet conveying jig 82 is of a structure with plural ID pins attached thereto. For example, in the example shown in FIGS. 18 and 19, four ID pins 88A to 88D are attached to the tablet conveying jig 82. The ID pins 88A to 88D each indicate the type (identification mark) of package to be produced. As shown in FIG. 20, by using the four ID pins 88A to 88D and by recognizing each of those ID pins automatically it is possible to assign sixteen (0 to 15) IDs to the tablet conveying jig 82. The tablet conveying jig 82 of the structure with four ID pins 88A to 88D attached thereto can cope with sixteen types of package manufacturing processes. In FIG. 20, each portion represented by “0” indicates the absence of ID pin, while each portion represented by “1” indicates the presence of ID pin. The structure with ID pins 88A-88D attached to the tablet conveying jig 82 may be substituted by a structure wherein holes corresponding to the ID pins 88A to 88D can be opened as necessary and the presence or absence of such holes is recognized automatically, thereby assigning IDs to the tablet conveying jig 82.

Even different types of tablets can be conveyed using a common tablet conveying jig 82 by forming the tablets so as to become equal in size, especially in plane diameter (first plane size) corresponding to each hole 83 in the tablet conveying jig 82. The type of each tablet being conveyed can be identified from ID pins 88A to 88D attached to the tablet conveying jig 82.

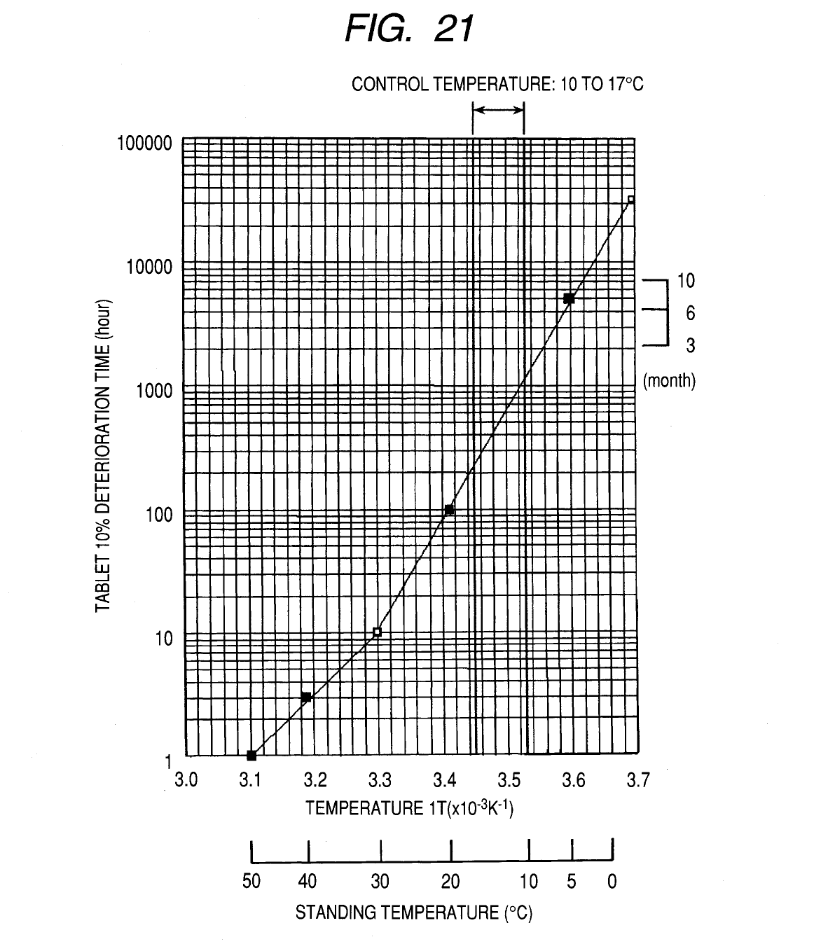

In this first embodiment each of the tablet stockers 81 has a structure permitting the interior thereof to be held at a constant temperature (first temperature) capable of suppressing deterioration of the tablet quality. FIG. 21 is an explanatory diagram showing a relation between the tablet control temperature and time taken to 10% deterioration of the tablet quality. It is in about seven days at the longest that a tablet is actually used and it is seen from FIG. 21 that the temperature permitting maintenance of the tablet quality for seven days or more is not higher than 17° C. If a practical temperature range is taken into account, an example of maintaining the interior of each tablet stocker 81 at about 10° C. to 17° C. can be shown in this first embodiment. By such a temperature control each of the tablet stockers 81 can store tablets while suppressing the deterioration of the tablet quality.

For carrying out the molding process by means of the molding apparatus according to this first embodiment shown in FIGS. 16 and 17, lead frames 1 before molding are set into a lead frame supply rack 90 installed within the frame supply unit FSU. In the interior of the lead frame supply rack 90, the portion where the lead frames 1 are set has a structure such that the lead frames 1 can be set separatedly type by type in conformity with the number of molding press sets MPS1 to MPS4 disposed within the press units PU1 to PU4. The molding press sets MPS to MPS4 are disposed respectively for the press units PU1 to PU4. In the frame supply unit FSU there is provided a motor (not shown) for sending out each lead frame 1 from the lead frame supply rack 90 to a lead frame aligning section LFL and shooting it to a position where the lead frame is to be picked up by a lead frame conveying unit to be described later. The amount of operation of this motor is set automatically so as to give a shoot width and a feed quantity both matching the size of the lead frame 1.

When the lead frame 1 is shot to the position where it is picked up by the lead frame conveying unit to be described later, a selected one of the ID pins 88A to 88D is attached thereto and the tablet conveying jig 82 with ID corresponding to the shot lead frame assigned thereto (none of the ID pins 88A to 88D is assigned in case of ID being “0” as shown in FIG. 20) is conveyed to the tablet supply unit TSU. Next, ID is recognized automatically from the ID pin attached to the tablet conveying jig 82, then the tablet conveying jig 82 is conveyed to the tablet stocker 81 in which are stored tablets corresponding to that ID (with the corresponding identification mark assigned thereto) and tablets 89 are supplied to the tablet conveying jig 82. After the supply of the tablets 89, the tablet conveying jig 82 is returned to the frame supply unit FSU.

Next, the tablet conveying jig 82 thus supplied with the tablets 89 is sent out together with the lead frame 1 to the pickup position by the lead frame conveying unit. At this position, the identification mark assigned to the lead frame 1 and the ID indicated by the ID pin attached to the tablet conveying jig 82 are recognized automatically to make sure that both are IDs corresponding to the lead frame 1 to be picked up by the lead frame conveying unit. Once it is made sure that the ID of the tablet conveying jig 82 is the ID corresponding to the lead frame 1, both lead frame 1 and tablet conveying jig 82 are picked up by the lead frame conveying unit and are conveyed to any corresponding one of the molding press sets (molding press jigs) MPS1-MPS4 installed within the press units. Before conveyance of the lead frame 1 and the tablet conveying jig 82 to any corresponding one of the molding press sets MPS1-MPS4, the identification mark assigned to the lead frame 1, the ID which the ID pin attached to the tablet conveying jig 82 indicates, and the identification mark assigned to the molding press set, are recognized automatically to make sure that the lead frame 1, the tablet conveying jig 82 and the molding press set correspond to one another.

The lead frame conveying unit is driven by a motor. As is the case with the motor provided in the frame supply unit FSU, the amount of operation of the motor for the lead frame conveying unit is set automatically so that the lead frame conveying unit operates in an amount of movement matching the size of the lead frame 1. The operation of the lead frame conveying unit controlled by the motor in question includes the operation of frame chuck portions which hold the lead frame 1 and the tablet conveying jig 82 and the operation of the lead frame conveying jig (to be shown later) which includes the frame chuck portions holding the lead frame 1 and the tablet conveying jig 82 (e.g., movement from the frame supply unit FSU to any corresponding one of the molding press sets MPS1-MPS4 and movement from the corresponding one of MPS1-MPS4 to the unloader unit ULU).

The molding die described above in connection with FIGS. 6 to 11 is attached to any of the molding press sets MPS1 to MPS4. The molding die has a structure conforming to the size of the lead frame being conveyed and the standard of the package to be formed. The molding press sets MPS1 to MPS4 can each be disposed plurally in a fixed or coupled state within the press units PU1 to PU4 and can be operated each individually. The molding press sets can thus be disposed plurally within the press units PU1 to PU4, but in this first embodiment four molding press sets MPS1 to MPS4 are disposed as in FIG. 17, taking into account an increase in size of the molding apparatus. In each of the molding press sets MPS1 to MPS4, the molding die attached thereto is replaceable. The molding press sets MPS1 to MPS4 have each a structure wherein the portion provided with an upper mold and the portion provided with a lower mold are opened or closed by means of a motor. The amount of operation of the motor is set automatically so that the amount of the opening or closing (the amount of operation) of the upper and lower molds matches the size of the lead frame 1. As described above in connection with FIGS. 6 to 11, the molding die used in this first embodiment is of the structure corresponding to one lead frame 1. Thus, since plural molding press sets MPS1 to MPS4 are disposed within the press units PU1 to PU4, the molding apparatus used in this first embodiment can perform molding for plural types of lead frames 1 at a time.

Further, identification marks (not shown) are assigned to the molding press sets MPS1 to MPS4 respectively, so when a lead frame 1 is conveyed, it is possible to recognize the corresponding molding press set by reading the identification marks.

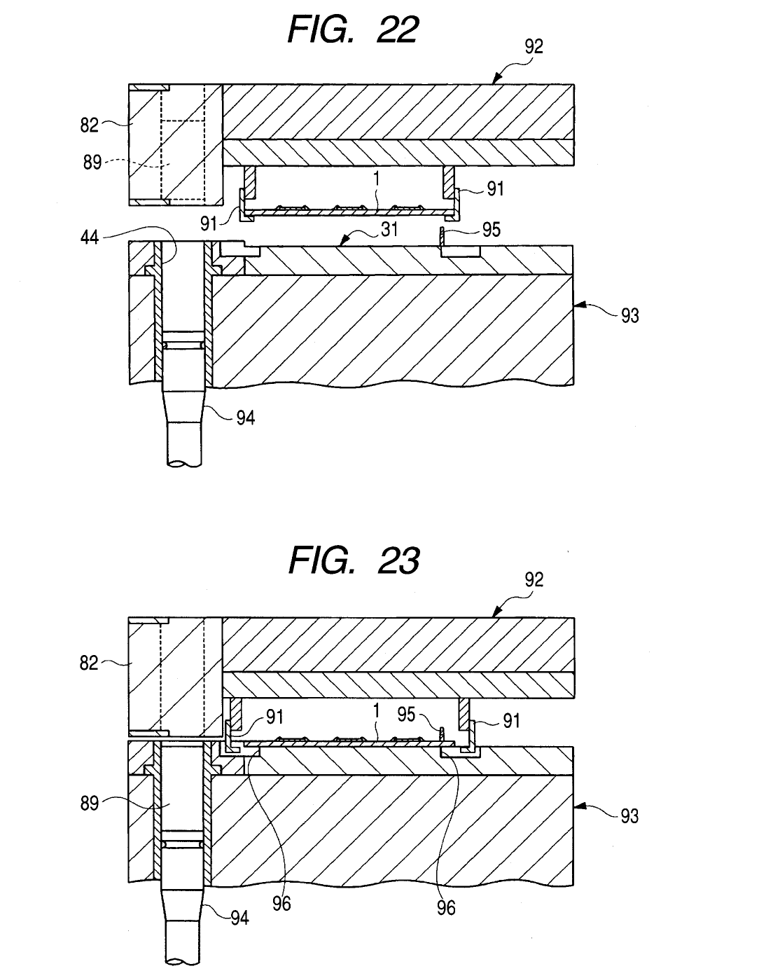

Now, with reference to FIGS. 22 to 25, a detailed description will be given below about the operation of the molding press sets MPS1 to MPS4 from when disposing a lead frame 1 to any corresponding one of the molding press sets MPS1 to MPS4 and until when the molding process is completed.

First, as shown in FIG. 22, a lead frame conveying jig 92 which includes frame chuck portions 91 holding the lead frame 1 and the tablet conveying jig 82 is moved onto a lower mold 93 corresponding to any corresponding one of the molding press sets MPS1 to MPS4. Within the pot portions 44 of the lower mold 93 are provided plungers 94 whereby the tablets 89 later fed into the pot portions 44 are injected, pressurized and held into the cavity portions 41 (see FIG. 7).

Next, as shown in FIG. 23, the lead frame conveying jig 92 is brought down, allowing the lead frame 1 to be disposed in the area 31 (see FIGS. 7 and 22) of the lower mold 93. In this case, the lead frame 1 is disposed in the area 31 in such a manner that holes (see FIG. 1) formed in the lead frame are fitted on positioning pins 95 provided in the area 31, whereby the lead frame 1 can be disposed at an exact position in the area 31. At this time, the tablets 89 are inserted into the pot portions 44 (see FIG. 22).

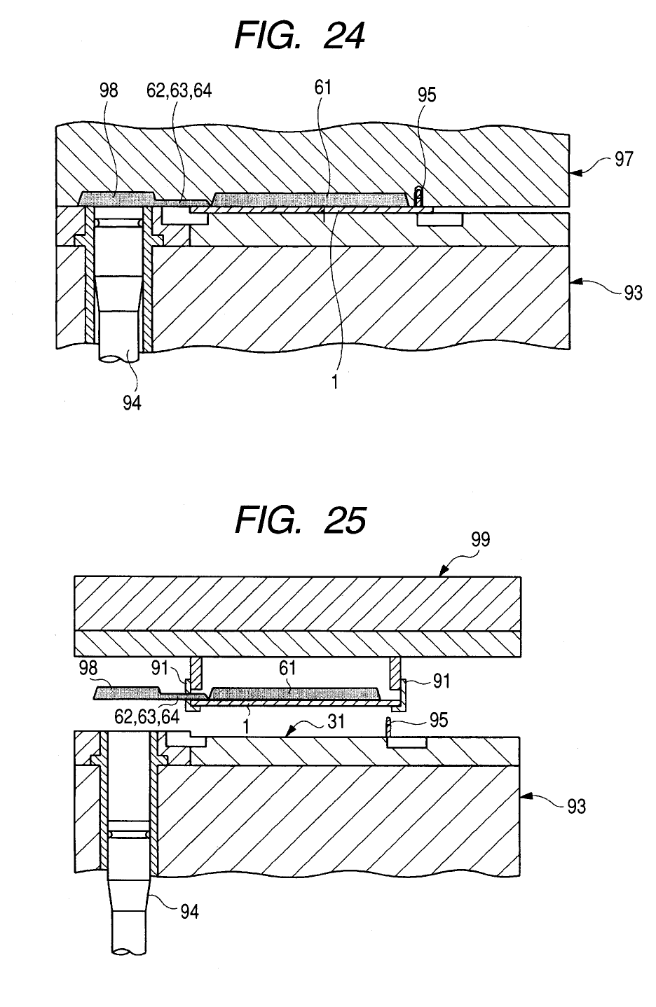

Next, as shown in FIG. 24, the frame chuck portions 91 are operated so as to move away from the lead frame 1 along frame chuck relief grooves 96 (see FIG. 23), thereby unchucking the lead frame 1 chucked by the frame chuck portions 91. Subsequently, the lead frame conveying jig 92 is raised and retracted. At this time, the lead frame conveying jig 92 conveys the tablet conveying jig 82 to the frame supply unit FSU. Then, an upper mold 97 is closed and the tablets 89 are pressurized by the plungers 94 to inject resin into the cavity portions 32 and 41 (see FIGS. 6 and 7) of the molding die, thereby sealing the chips 21 (see FIG. 3) with resin 61. At this time, resin 62 remaining in the gate portions, resin 63 remaining in the runner portions, resin 64 remaining in the sub-runner portions and resin 98 remaining in the cull portions 35, which have been described above in connection with FIG. 4, are also formed.

Next, as shown in FIG. 25, after opening the upper mold 97, a lead frame conveying jig 99 for conveying the lead frame 1 to the unloader unit ULU is moved onto the lead frame 1. The lead frame conveying jig 99 is provided with the frame chuck portions 91 used in the lead frame conveying jig 92 (see FIGS. 22 and 23) described above. Subsequently, the lead frame conveying jig 99 is brought down and the frame chuck portions 91 are moved along the frame chuck relief grooves 96 to hold the lead frame 1. In this state the lead frame conveying jig 99 is raised to convey the lead frame to the unloader unit ULU.

In each of the press units PU1 to PU4 any of the molding press sets MPS1 to MPS4 is stopped alone because the molding dies provided in the molding press sets MPS1 to MPS4 are subjected periodically to such a work as a cleaning work as a manual work. According to the structure concerned, the loading and unloading of the lead frame 1 can be done from the back side opposite to the molding work side so that the other molding press sets MPS1-MPS4 than the stopped one can operate. That is, the molding die cleaning work for example is performed from the molding work side.

The lead frame 1 which has been conveyed to the unloader unit ULU is then transferred to a gate break section 100 (see FIG. 17) in the unloader unit ULU. In the gate break section 100, the resin 62 remaining in the gate portions, resin 63 remaining in the runner portions, resin 64 remaining in the sub-runner portions and resin 98 remaining in the cull portions 35 are removed. In this case, the resin 62 remaining in the gate portions, resin 63 remaining in the runner portions and resin remaining in the sub-runner portions are removed after removal of the resin 98 remaining in the cull portions 35. These resin removing operations can be done by the method described previously in connection with FIG. 12. The lead frames 1 after completion of removal of the resin 62 remaining in the gate portions, resin 63 remaining in the runner portions, resin 64 remaining in the sub-runner portions and resin 98 remaining in the cull portions 35 are received in a lead frame receptacle section 101 (see FIG. 17) in a separated manner type by type.

According to this first embodiment, as described above, the frame supply unit FSU, the lead frame conveying unit and the molding press sets MPS1 to MPS4 are operated respectively by motors within the molding apparatus (see FIGS. 16 and 17). The amount of operation of each motor is controlled in accordance with preset data so as to given an amount of operation matching the size of the lead frame 1 concerned. When the type of the lead frame 1 changes to another type, the data concerned is read and the amount of operation of each motor switches automatically. Thus, the frame supply unit FSU, the lead frame conveying unit and the molding press sets MPS1 to MPS4 are employable as they are even if the type of the lead frame 1 changes. That is, it is possible to effect automation of the molding process suitable for the multifarious small lot package manufacturing process. Besides, since it is no longer necessary to fabricate those constituent units and sets for each type of the lead frame 1, it is possible to reduce the cost required for them and hence possible to reduce the multifarious small lot package manufacturing cost.

According to this first embodiment, moreover, the frame supply unit FSU, the lead frame conveying unit and the molding press sets MPS1 to MPS4 are employable as they are even if the type of the lead frame 1 changes, and since the amount of operation of each of the motors for operating those units and sets switches automatically, the work for replacing them to match the type of the lead frame 1 can be omitted. Since the amount of operation of each motor switches automatically, it is also possible to omit fine adjustment of those members when the type of the lead frame 1 changes. As a result, it is possible to shorten the TAT (Turn Around Time) of the multifarious small lot package production.

Further, according to the first embodiment described above, the molding process can be carried out automatically without going through manual operation of a worker in charge of maintenance. Consequently, it is possible to shorten the TAT of the package production in this first embodiment. Besides, since the molding process is carried out automatically without going through manual operation of the worker in charge of maintenance, it is possible to stabilize the conveyance of the lead frame 1 in the molding apparatus and hence possible to improve the package manufacturing yield.

### Second Embodiment

This second embodiment concerns a case where the width (see FIG. 1) in Y direction of the lead frame 1 is narrow. The following description is provided about the operation of the molding press sets MPS1 to MPS4 from when disposing the lead frame 1 to any corresponding one of the molding press sets MPS1-MPS4 until completion of the molding process as described above in the first embodiment in connection with FIGS. 22 to 25.

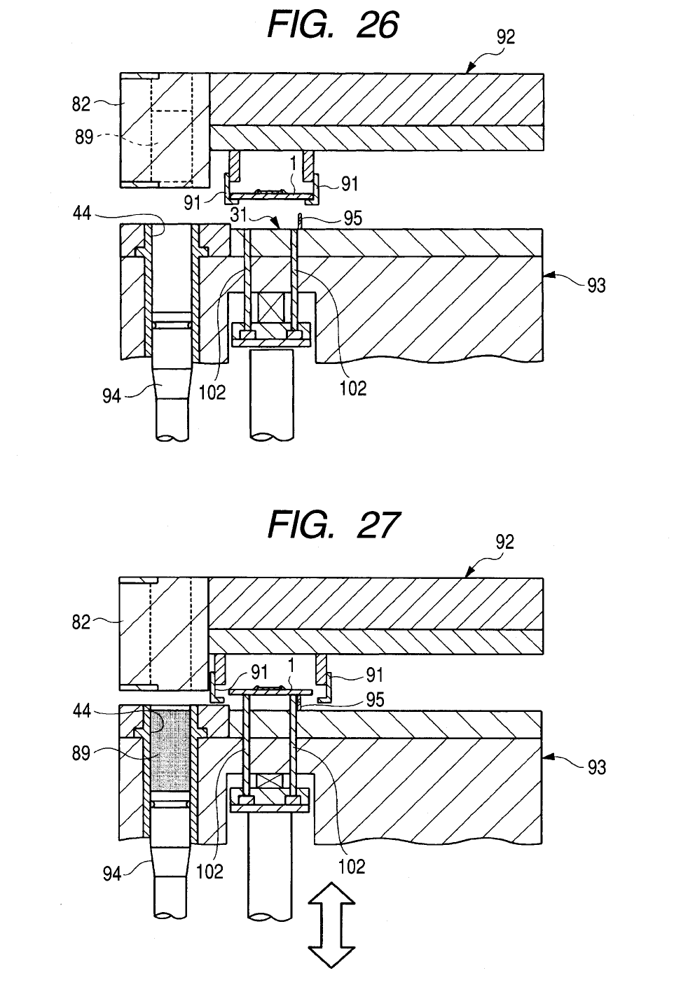

First, as shown in FIG. 26, the lead frame conveying jig 92 including the frame chuck portions which hold the lead frame 1 and the tablet conveying jig 82 is moved onto the lower mold 93 in any corresponding one of the molding press sets MPS1-MPS4. Ejector pins 102 capable of ejecting the lead frame 1 after mounting of the same frame onto the area 31 of the lower mold 93 and holding it in a floated state from the area 31 underlie the area 31.

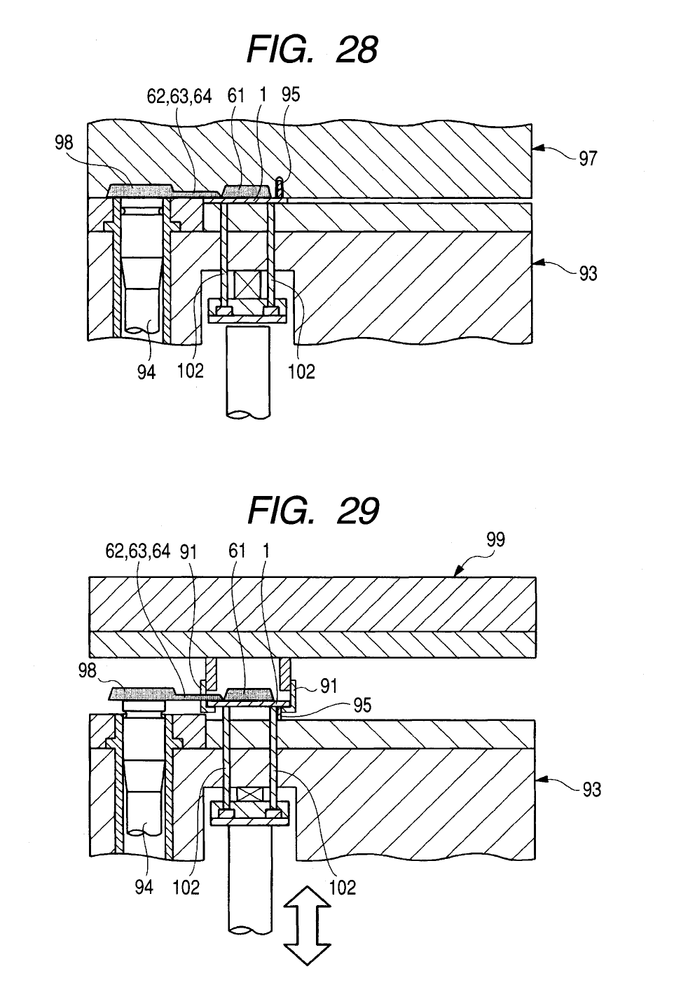

Next, as shown in FIG. 27, after the ejector pins 102 are pushed up a predetermined amount, the lead frame conveying jig 92 is brought down, allowing the lead frame 1 to be disposed on the ejector pins 102 thus pushed up. Subsequently, as shown in FIG. 28, the frame chuck portions 91 are operated so as to move away from the lead frame 1, whereby the chucked state of the lead frame 1 by the frame chuck portions is released. Then, the lead frame conveying jig 92 is raised and retracted. In this case, the lead frame conveying jig 92 conveys the table conveying jig 82 to the frame supply unit FSU. Next, the ejector pins 101 are brought down and the lead frame 1 is disposed on the area 31 (see FIG. 27). At this time, the positioning pins 95 provided in the area 31 are passed through the holes 15 (see FIG. 1) formed in the lead frame 1, whereby the lead frame 1 is disposed at an exact position on the area 31. At the same time, the tablets 89 (see FIG. 27) are inserted into the pot portions 44 (see FIG. 27).

Then, the upper mold 97 is closed and the tablets 89 are pressurized by the plungers 94, whereby resin is injected into the cavity portions 32 and 41 (see FIGS. 6 and 7) of the molding die to seal the chips 21 (see FIG. 3) with resin 61. At this time, resin 62 remaining in the gate portions, resin 63 remaining in the runner portions, resin 64 remaining in the sub-runner portions and resin 98 remaining in the cull portions 35, which have been described above in connection with FIG. 4, are also formed.

Next, as shown in FIG. 29, after the upper mold 97 is opened, the lead frame conveying jig 99 for conveying the lead frame 1 to the unloader unit ULU is moved onto the lead frame 1. The lead frame conveying jig 99 is provided with the frame chuck portions 91 in the lead frame conveying jig 92 (see FIGS. 26 and 27) described above. Subsequently, the lead frame 1, as well as the resin 62 remaining in the gate portions, resin 63 remaining in the runner portions, resin 64 remaining in the sub-runner portions and resin 98 remaining in the cull portions 35 are pushed up by the ejector pins 102 and the plungers 94. Then, the lead frame conveying jig 99 is brought down and the frame chuck portions 91 are operated to hold the lead frame 1. In this state the lead frame conveying jig 99 is raised and is conveyed to the unloader unit ULU. Subsequent steps are the same as the steps described in the first embodiment and following conveyance of the lead frame 1 to the unloader unit ULU.

This second embodiment is effective particularly in the case where the frame chuck relief grooves (see FIG. 23) described in the first embodiment are not formed because of a limitation on the size of the lead frame 1.

Also by this second embodiment it is possible to obtain the same effects as in the first embodiment.

### Third Embodiment

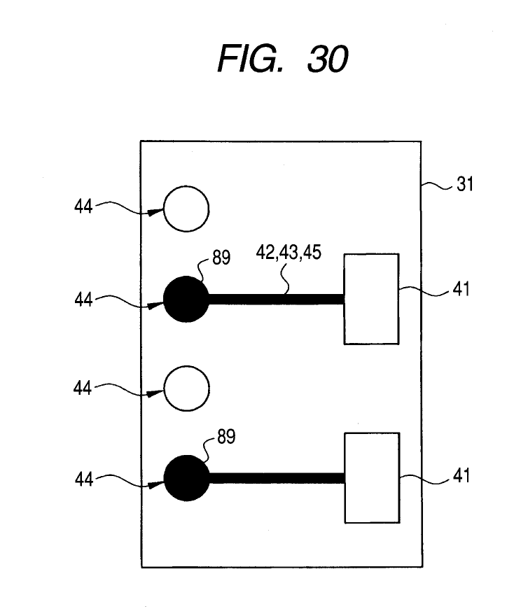

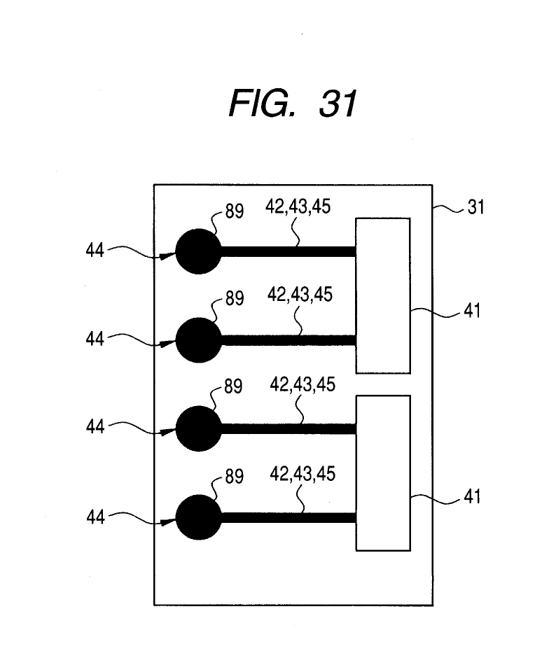

FIGS. 30 and 31 are plan views of principal portions of lower molds for explaining resin influent paths in molding dies (lower molds) according to this third embodiment.

In this third embodiment, as shown in FIG. 30, when the size of the package to be fabricated is small and so is the size of each cavity portion 41, only selected ones of pot portions 44 are coupled to the cavity portions 41 through gate portions 42, runner portions 43 and sub-runner portions 45 and tablets 89 are supplied to only the pot portions 44 coupled to the cavity portions 41. In this case, in the pot portions 44 not supplied with tablets 89, the plungers 94 (see FIGS. 22 to 29) perform a lost motion. In the case where the size of the package to be fabricated is large and so is the size of each cavity portion 41, as shown in FIG. 31, plural pot portions 44 are coupled to one cavity portion 41 through gate, runner and sub-runner portions 42, 43, 45 and tablets 89 are supplied to all the pot portions 44.

According to this third embodiment described above, the size of each tablet 89 can be made common irrespective of the package size. Besides, the standard and the number of plungers 94 to be disposed can also be made common irrespective of the package size. Therefore, in the molding press sets MPS1 to MPS4, the other members than the molding die (upper and lower molds) can be made common. As a result, it is possible to simplify the molding die replacing work and hence possible to further shorten the TAT (Turn Around Time) in multifarious small lot package production.

Also by this third embodiment described above it is possible to obtain the same effects as in the above first and second embodiments.

Although the present invention has been described above concretely on the basis of embodiments thereof, it goes without saying that the present invention is not limited to the above embodiments and that various changes may be made within the scope not departing from the gist of the invention.

For example, although in the above embodiments there is used a lead frame as a substrate for mounting chips thereon, the lead frame may be substituted by a multi-layer wiring substrate having multiple wiring layers.

The semiconductor device manufacturing method of the present invention is applicable for example to a semiconductor device manufacturing process using a lead frame with chips mounted thereon and resin-sealed at main surfaces thereof.

What is claimed is:

1. A method of fabricating a semiconductor device, using a molding apparatus for sealing plural types of bases with resin and comprising the steps of:
(a) mounting semiconductor chips over any of the bases;
(b) conveying the base with the semiconductor chips mounted thereover to a molding press jig in the molding apparatus;
(c) conveying tablets as sealing resin to the molding press jig;
(d) pressing the tablets in the molding press jig to seal the semiconductor chips with the sealing resin; and
(e) after the step (d), unloading the base from the molding press jig,
wherein the molding apparatus includes a plurality of tablet storage means for storing plural types of the tablets type by type and a plurality of the molding press jigs having one molding die, the one molding die having a structure permitting insertion therein of one said base, with identification marks indicative of types fabricated being assigned to the bases, the tablet storage means and the molding press jigs respectively, in the step (b) the identification mark of the base is read and the base is conveyed to the molding press jig with the corresponding identification mark assigned thereto, and in the step (c) the tablets are taken out from the tablet storage means to which is assigned the identification mark corresponding to the identification mark read from the base in the step (b) and are then supplied to the molding press jig with the corresponding identification mark assigned thereto.

2. A method according to claim 1, wherein the interior of each of the tablet storage means is held at a first temperature capable of maintaining the quality of the tablets.

3. A method according to claim 2, wherein the first temperature is in the range of 10 to 20° C.

4. A method according to claim 1, wherein the molding die provided in the molding press jigs can be replaced with another type of the molding die.

5. A method according to claim 1, wherein the molding press jigs provided in the molding apparatus can be operated each individually.

6. A method according to claim 1, wherein the amount of movement of each of the bases during conveyance in the molding apparatus is registered beforehand in the molding apparatus for each of the identification marks, and in the step (b) the base is conveyed to the corresponding molding press jig in the amount of movement corresponding to the read identification mark of the base.

7. A method according to claim 1, wherein the amount of operation of the molding press jig corresponding to each of the identification marks is registered beforehand in the molding apparatus for each of the identification marks and the molding press jig operates in the amount of operation corresponding to the identification mark assigned thereto.

8. A method according to claim 1, wherein the molding apparatus has four said molding press jigs.

9. A method of fabricating a semiconductor device, using a molding apparatus for sealing plural types of bases with resin and comprising the steps of:
(a) mounting semiconductor chips over any of the bases;
(b) conveying the base with the semiconductor chips mounted thereover to a molding press jig in the molding apparatus;
(c) conveying tablets as sealing resin to the molding press jig;
(d) pressing the tablets in the molding press jig to seal the semiconductor chips with the sealing resin; and
(e) after the step (d), unloading the base from the molding press jig,
wherein the molding apparatus includes a plurality of tablet storage means for storing plural types of the tablets type by type, a plurality of the molding press jigs having one molding die and a plurality of tablet conveying jigs for holding the tablets and supplying them to the molding press jig, the plural types of the tablets having one and same first plane size, the one molding die having a structure permitting insertion therein of one said base, with identification marks indicative of types to be fabricated being assigned to the bases, the tablet storage means and the molding press jigs respectively, in the step (b) the identification mark of the base is read and the base is conveyed to the molding press jig with the corresponding identification mark assigned thereto, and in the step (c) the tables are taken out from the tablet storage means to which is assigned the identification mark corresponding to the identification mark read from the base in the step (b) and are then supplied to the molding press jig with the corresponding identification mark assigned thereto, and the tablet conveying jig holding the tablets is conveyed to the molding press jig with the corresponding identification mark assigned thereto.

10. A method according to claim 9, wherein the interior of each of the tablet storage means is held at a first temperature capable of maintaining the quality of the tablets.

11. A method according to claim 10, wherein the first temperature is in the range of 10 to 20° C.

12. A method according to claim 9, wherein the molding die provided in the molding press jigs can be replaced with another type of the molding die.

13. A method according to claim 9, wherein the molding press jigs provided in the molding apparatus can be operated each individually.

14. A method according to claim 9, wherein the amount of movement of each of the bases during conveyance in the molding apparatus is registered beforehand in the molding apparatus for each of the identification marks, and in the step (b) the base is conveyed to the corresponding molding press jig in the amount of movement corresponding to the read identification mark of the base.

15. A method according to claim 9, wherein the amount of operation of the molding press jig corresponding to each of the identification marks is registered beforehand in the molding apparatus for each of the identification marks and the molding press jig operates in the amount of operation corresponding to the identification mark assigned thereto.

16. A method according to claim 9, wherein the molding apparatus has four said molding press jigs.

17. A method of fabricating a semiconductor device, using a molding apparatus for sealing plural types of bases with resin and comprising the steps of:
(a) mounting semiconductor chips over any of the bases;
(b) conveying the base with the semiconductor chips mounted thereover to a molding press jig in the molding apparatus;
(c) conveying tablets as sealing resin to the molding press jig;
(d) pressing the tablets in the molding press jig to seal the semiconductor chips with the sealing resin; and
(e) after the step (d), unloading the base from the molding press jig,
wherein the molding apparatus includes a plurality of tablet storage means for storing a plurality of the tablets of the same type and a plurality of the molding press jigs having one molding die, the one molding die having a structure permitting insertion therein of one said base, with identification marks indicative of types to be fabricated being assigned to the bases and the molding press jigs respectively, in the step (b) the identification mark of the base is read and the base is conveyed to the molding press jig with the corresponding identification mark assigned thereto, and in the step (c) the tablets in the number of tablets corresponding to the identification mark read from the base in the step (b) are taken out from the tablet storage means and are then supplied to the molding press jig with the corresponding identification mark assigned thereto.

18. A method according to claim 17, wherein the interior of each of the tablet storage means is held at a first temperature capable of maintaining the quality of the tablets.

19. A method according to claim 18, wherein the first temperature is in the range of 10 to 20° C.

20. A method according to claim 17, wherein the molding press jigs have a plurality of pots to which the tablets are supplied, and in the step (c) the tablets are not supplied to any of the pots not coupled to cavities of the molding die.

21. A method according to claim 17, wherein the molding press jigs provided in the molding apparatus can be operated each individually.

22. A method according to claim 17, wherein the amount of movement of each of the bases during conveyance in the molding apparatus is registered beforehand in the molding apparatus for each of the identification marks, and in the step (b) the base is conveyed to the corresponding molding press jig in the amount of movement corresponding to the
